(19) United States
(12) Patent Application Publication
(10) Pub. No.: US 2017/0263461 A1
(43) Pub. Date: Sep. 14, 2017

(54) PLASMA PROCESSING METHOD

(71) Applicant: Panasonic Intellectual Property Management Co., Ltd., Osaka (JP)

(72) Inventors: NORIYUKI MATSUBARA, Osaka (JP); ATSUSHI HARIKAI, Osaka (JP); AKIHIRO ITOU, Kyoto (JP)

(21) Appl. No.: 15/427,198

(22) Filed: Feb. 8, 2017

(30) Foreign Application Priority Data
Mar. 9, 2016 (JP) 2016-045343

(51) Int. Cl. H01L 21/3065; H01L 21/78; H01L 21/268; H01L 21/308; H01L 21/311

(52) U.S. Cl. CPC H01L 21/3065; H01L 21/3081; H01L 21/3086; H01L 21/31133; H01L 21/268; H01L 21/78

(57) ABSTRACT

A plasma processing method includes an attaching process of attaching a resin film to a first main surface of a substrate which is provided with the first main surface and a second main surface on an opposite side of the first main surface and a patterning process of forming a mask, which includes an opening exposing a region to be processed of the substrate, by patterning the resin film. The plasma processing method includes a first plasma process of generating first plasma of first gas in a depressurized atmosphere including the first gas, exposing the mask to the first plasma, and reducing a void between the mask and the first main surface. The plasma processing method includes a second plasma process of generating second plasma from second gas in atmosphere including the second gas, exposing the region to be processed exposed from the opening to the second plasma, and etching the region to be processed.

### BACKGROUND

1. Technical Field

The present disclosure relates to a plasma processing method of which a process of patterning a resin film attached to a main surface of a substrate and a process of performing a plasma process on the substrate are combined.

2. Description of the Related Art

Patterning using a laminate mask (for example, dry film resist) makes a manufacturing process of a semiconductor circuit, an electronic circuit, or the like simplified, and there is a demand that the patterning is used in many ways. However, in a process of attaching a laminate mask to a main surface of a substrate, air is likely to be interposed between the laminate mask and the main surface of the substrate, and therefore, a minute void is inevitably formed (refer to PTL 1). In order to reduce such a phenomenon, it is necessary to perform the process of attaching in a highly depressurized atmosphere, but this causes an increase in cost or complication of the process. The laminate mask includes minute unevenness on a surface of the mask, and the minute unevenness is also present on the main surface of the substrate. Therefore, the phenomenon, in which the void is formed between the laminate mask and the main surface of the substrate, is not easy to avoid in principle.

In a field where precision etching is not required, the minute void between the laminate mask and the main surface of the substrate does not matter. However, in a case in which the precision etching is required, at least a part of the mask is floated from the main surface of the substrate in a region where the void is present. Therefore, an extra part of the substrate is etched in a subsequent etching process, and a final product becomes easily faulty.

### CITATION LIST

### Patent Literature

PTL 1: Japanese Patent Unexamined Publication No. 3-141358

### SUMMARY

This disclosure is provided to etch a substrate in a precision pattern by a simple process.

An aspect of the disclosure relates to a plasma processing method, and includes processes as follows. That is, the plasma processing method includes an attaching process of attaching a resin film to a first main surface of a substrate which is provided with the first main surface and a second main surface on an opposite side of the first main surface and a patterning process of forming a mask, which includes an opening exposing a region to be processed of the substrate, by patterning the resin film.

The plasma processing method includes a first plasma process of generating first plasma of first gas in a depressurized atmosphere including the first gas, exposing the mask to the first plasma, and reducing a void between the mask and the first main surface. The plasma processing method includes a second plasma process of generating second plasma from second gas in atmosphere including the second gas, exposing, to the second plasma, the region to be processed exposed from the opening, and etching the region to be processed.

According to the plasma processing method of the disclosure, when attaching the resin film to the main surface of the substrate, the substrate can

be etched in a precision pattern even in a case in which a minute void is interposed between the resin film and the main surface of the substrate.

### BRIEF DESCRIPTION OF THE DRAWINGS

FIG. 1 is a perspective schematic sectional view illustrating a structure of an example of a plasma processing apparatus which is used for a plasma processing method according to an embodiment of the disclosure;

FIG. 2A is a perspective process view illustrating a process of the plasma processing method according to the embodiment of the disclosure;

FIG. 2B is perspective process view illustrating the process of the plasma processing method according to the embodiment;

FIG. 2C is a perspective process view illustrating the process of the plasma processing method;

FIG. 2D is a perspective process view illustrating the process of the plasma processing method;

FIG. 2E is a perspective process view illustrating the process of the plasma processing method;

FIG. 2F is a perspective process view illustrating the process of the plasma processing method;

FIG. 3A is a perspective process view illustrating a process of another plasma processing method according to the embodiment of the disclosure;

FIG. 3B is a perspective process view illustrating the process of the plasma processing method according to the embodiment;

FIG. 3C is a perspective process view illustrating the process of the plasma processing method;

FIG. 3D is a perspective process view illustrating the process of the plasma processing method;

FIG. 3E is a perspective process view illustrating the process of the plasma processing method; and

FIG. 3F is a perspective process view illustrating the process of the plasma processing method.

### DETAILED DESCRIPTION

A plasma processing method according to an embodiment of the disclosure includes a process (attaching process) of attaching a resin film to a first main surface of a substrate which is provided with the first main surface and a second main surface of an opposite side thereof. The attaching process is not a process of forming a resin layer by applying liquid resist, but is a process of attaching a resin film prepared in advance to the first main surface of the substrate. At this time, a minute void is formed between the resin film and the first main surface, but the void can be reduced in a subsequence first plasma process, and thus the attaching process does not need to be performed in a depressurized atmosphere.

The resin film may have adhesion, which can be used for being attached to the first main surface of the substrate, the types, structures, and the like of the resin film are not particularly limited. The resin film may be an adhesive layer having adhesion, but may include a base sheet in order to improve handling properties. In general, after the adhesive layer held on the base sheet is used and the adhesive layer is attached on the first main surface of the substrate, the base sheet is peeled off. In this case, the resin film is configured with only the adhesive layer.

As the resin film, an adhesive layer not having photosensitivity, such as polyvinyl alcohol (PVA), or an acrylic based adhesive agent, as a base material may be used, and an adhesive layer (resist layer) having photosensitivity may be used. Among these layers, various types of the resist layer (dry film resist) held on the base sheet are commercially available, and thus the resist layer can be easily get.

As the base sheet, for example, a polyester film is used. In a case of the dry film resist on the market, a three-layer structure in which the adhesive layer is covered with a cover film is provided. In the cover film, for example, a polyethylene film is used. A material of the base sheet may be vinyl chloride (PVC), polyethylene, polyethylene terephthalate, or the like may be used, in addition to polyester described above.

Since a substrate as a target to be etched may be various circuit members, it is not particularly limited, and a semiconductor substrate such as a silicon wafer, a resin substrate such as a flexible printed substrate, and a ceramic substrate, are exemplified. As a semiconductor constituting the semiconductor substrate, for example, silicon (Si), gallium arsenide (GaAs), gallium nitride (GaN), silicon carbide (SiC), and the like are exemplified.

The semiconductor substrate may include a circuit layer on the first main surface thereof. The circuit layer may include at least an insulating film, and in addition, a metal material, a resin protective layer, an electrode pad, and the like may be included. The insulating film may be included as a laminated body (multilayered wiring layer) of a metal material for wiring. The insulating film includes, for example, silicon dioxide (SiO₂), silicon nitride (Si₃N₄), a low dielectric constant film (Low-k film), a resin film such as polyimide, lithium tantalate (LiTaO₃), lithium niobate (LiNbO₃), and the like.

Next, a process (patterning process) of forming an opening, where a region to be processed of the substrate is exposed, on the resin film by patterning the resin film is performed. The patterning process is a process of forming a mask including the opening from the resin film, and a method thereof is not particularly limited.

In a case in which the dry film resist is used, in the patterning process, for example, a part corresponding to the opening of the mask of the resin film may be removed by wet-etching. In the wet etching, the resin film or the resist layer attached on the first main surface of the substrate is exposed in a desired pattern, and then the resist layer is soaked into etching solution so that a mask having an opening is formed. The type of the resist layer may be a positive type or a negative type.

In a case in which the resin film or the adhesive layer not having photosensitivity is used, in the patterning process, a part corresponding to the opening of the mask of the resin film or the adhesive layer may be removed for example, by scribing using laser.

Next, the depressurized atmosphere including first gas is formed on the vicinity of the substrate including the mask formed by patterning. Continuously, a process (first plasma process in which a void between the mask and the first main surface is reduced when the first plasma of the first gas is generated and the mask is exposed to the first plasma is performed. When the mask is exposed to the first plasma in the depressurized atmosphere, and air flows out from the inside of the void present on at least the vicinity of the opening of the mask, floating of the mask from the first main surface of the substrate is corrected. Accordingly, adhesion of the first main surface of the substrate and the mask is improved. Therefore, in a subsequence etching process, etching of an extra part of the substrate is suppressed, and the precision etching can be performed. If the etching is performed in a state in which the mask is floated from the first main surface of the substrate in the vicinity of the opening of the mask, etching is proceed on a part distant from the mask of the first main surface, and the precision etching becomes difficult.

In the first plasma process, it is desirable that at least a part of the mask is soften. Accordingly, adhesion of the first main surface of the substrate and the mask is further improved. Therefore, the mask is heated with the first plasma until at least a part of the mask reaches a softening temperature or more. In a case in which the mask is the adhesive layer or the resist layer, it is desirable that the mask is heated by controlling the first plasma so that a temperature of the mask becomes 60° C. to 110° C., more preferably 80° C. to 100° C.

Bias in a direction toward the substrate may be applied to the first plasma as needed.

It is desirable that the first gas does not include a chemical effect. Accordingly, it is preferable that the first gas includes at least one selected from a group constituting of argon, oxygen, nitrogen, and helium. At this time, it is preferable that a pressure of the depressurized atmosphere including the first gas is, for example, 0.1 Pa to 100 Pa, and more preferably, 0.5 Pa to 20 Pa.

Next, atmosphere including second gas is formed on the vicinity of the substrate on which the first plasma process is performed. Continuously, second plasma is generated from the second gas, and a region to be processed, which is exposed from the opening exposed to the second plasma, and thus a process (second plasma process) of etching a region to be processed is performed. At this time, it is preferable that continuously performing the first plasma process and the second plasma process in the same space is efficient.

The first plasma process and the second plasma process are performed, for example, in a process space inside a chamber provided in a dry etching device.

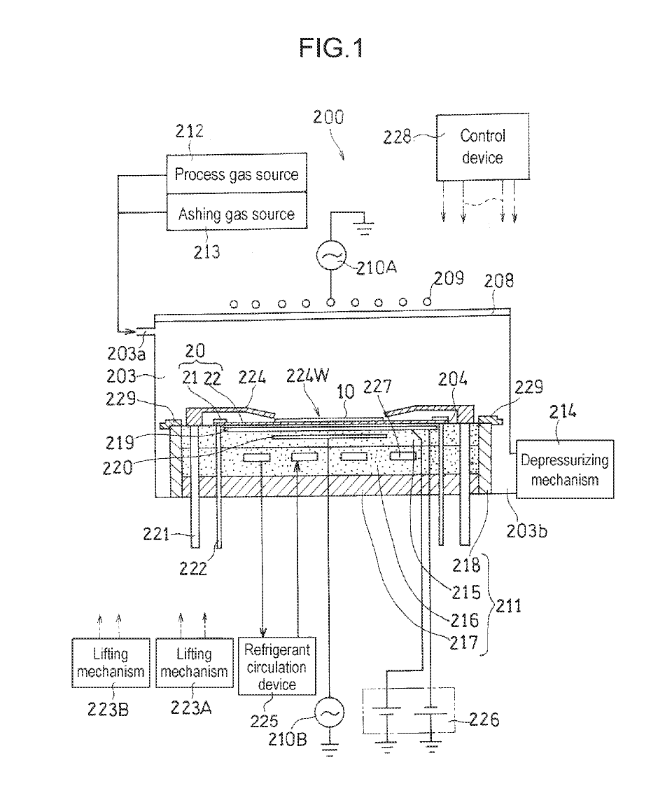

The second gas may be the same as the first gas, or may be different. That is, the second plasma may be generated in the same condition as that of the first plasma. However, in general, a condition of the first plasma necessary for reducing the void between the mask and the first main surface is different from a condition of the second plasma necessary for etching the region to be processed. The types and pressure of the second gas, the condition of the second plasma, and the like are appropriately selected according to the types of substrates to be etched. In the second plasma process, for example, the region to be processed is etched from the first main surface to the second main surface by the second plasma, and the substrate is divided into individual pieces. Such a process is, for example, suitable for plasma dicing of the semiconductor substrate using the dry etching device. Hereinafter, referring to drawings, an example of the plasma processing method according to an embodiment of the disclosure will be described. First, referring to FIG. 1, an example of a plasma processing apparatus, which is used at the time of performing the first plasma process and the second plasma process, will be described. However, the plasma processing apparatus is not limited thereto.

Plasma processing apparatus 200 is provided with vacuum chamber 203, and also provided with stage 211 in the processing space of the inside thereof. In vacuum chamber 203, gas introduction port 203a and exhaust port 203h are mounted. In gas introduction port 203a, process gas source 212 and aching gas source 213 are respectively connected. In exhaust port 203b, depressurizing mechanism 214, which includes a vacuum pump exhausting and depressurizing gas inside vacuum chamber 203, is connected.

In stage 211, substrate 10 held by transportation carrier 20 is mounted. Transportation carrier 20 is configured with circular frame 21 and holding sheet 22, frame 21 fixes the vicinity of holding sheet 22. Holding sheet 22 includes an adhesive surface for pasting the second main surface of substrate 10. A plurality of supporters 222 lifted and driven by lifting mechanism 223A are disposed on circumference of stage 211, and transportation carrier 20 transported into vacuum chamber 203 is delivered to supporter 222 and is mounted on stage 211.

Cover 224 including window 224W, which covers at least frame 21 and exposes substrate 10, is disposed above stage 211. Cover 224 is connected to a plurality of lifting rods 221 and is lifted and driven by lifting mechanism 223B. An upper part of vacuum chamber 203 is closed by dielectric member 208, and antenna 209 is disposed above dielectric member 208 as an upper electrode. Antenna 209 is connected to first high-frequency power source 210.A.

Stage 211 is provided with electrode layer 215, metal layer 216, and base 217 in order from the top, these are surrounded by circumference 218, and circumference ring 229 for protecting is disposed on an upper surface of circumference 218. Electrode (ESC electrode) 219 for electrostatic suction and high-frequency electrode 220 connected to second high-frequency power source 210B are disposed inside electrode layer 215. ESC electrode 219 is connected to DC power source 226. When high-frequency power is applied to high-frequency electrode 220, the first plasma process and/or the second plasma process can be performed while applying bias voltage. Refrigerant flow path 227 for cooling stage 211 is formed inside metal layer 216, and refrigerant is circulated by refrigerant circulation device 225.

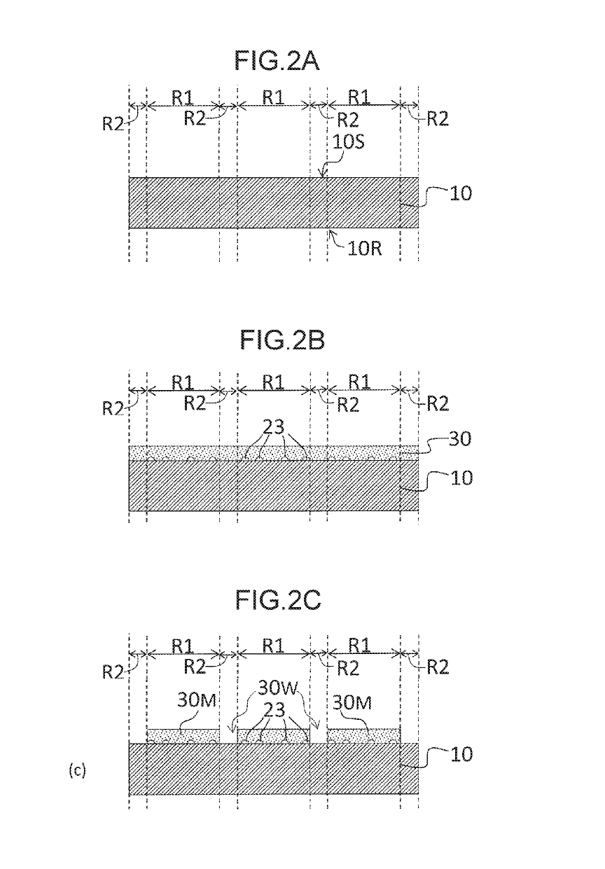

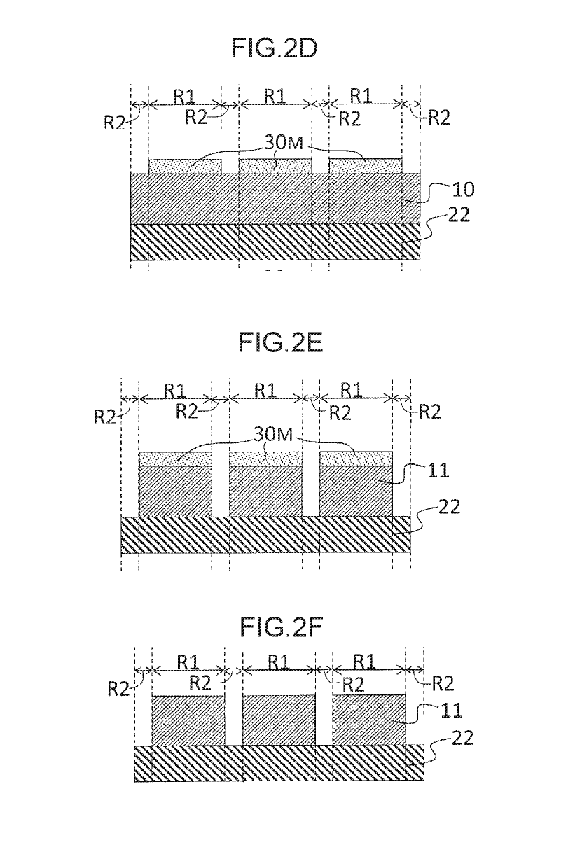

Control device 228 controls an operation of plasma processing apparatus 200 which includes first high-frequency power source 210A, second high-frequency power source 210B, process gas source 212, ashing gas source 213, depressurizing mechanism 214, refrigerant circulation device 225, lifting mechanism 223A, lifting mechanism 223B, and electrostatic suction mechanism. Next, referring to a schematic scheme illustrated in FIGS. 2A to 2F, an example of the plasma processing method according to the embodiment of the disclosure will be described. Here, a case in which the semiconductor substrate is divided into individual pieces in the second plasma process using the semiconductor substrate such as a silicon wafer as a substrate will be described. However, the plasma processing method according to the disclosure is not limited thereto.

First, semiconductor substrate 10 is prepared (FIG. 2A). Semiconductor substrate 10 includes a plurality of element regions R1 and region to be processed R2 where the plurality of element regions R1 are determined. Second main surface 10R of an opposite side of first main surface 10S of semiconductor substrate 10 may be attached to holding sheet 22 of transportation carrier 20 at this point, but may be arbitrarily attached to holding sheet 22. Semiconductor substrate 10 may be held on holding sheet 22, and may not be held on holding sheet 22.

A size of semiconductor substrate 10 is not particularly limited, and for example, has a maximum diameter of 50 mm to 300 mm. A shape of semiconductor substrate 10 is not particularly limited, and for example, may be circular or square. A thickness of the insulating film or multilayer wiring layer is not particularly limited, and for example, may be 2 μm to 10 μm. In semiconductor substrate 10 may be also provided with a notch such as an orientation flat and a notch (neither is illustrated). A circuit layer (neither is illustrated) such as a semiconductor circuit, an electronic component element, and MEMS may be formed on a surface of element region R1.

Next, a process of pasting resin film 30 to first main surface 10S of semiconductor substrate 10 is performed (FIG. 213). The resin film 30 includes minute unevenness on a surface thereof, and the minute unevenness is also present on main surface 10S of semiconductor substrate 10. Therefore, void 23 is inevitably formed between resin film 30 and first main surface 10S of semiconductor substrate 10. The process of pasting resin film 30 to first main surface 10S is not necessary to be performed in a depressurized atmosphere, but for example, may be performed in the depressurized atmosphere of substantially 0.1 Pa to 100 Pa.

Next, from resin film 30, a patterning process, in which mask 30M including opening 30W exposing region to be processed R2 of semiconductor substrate 10 is formed, is performed (FIG. 2C). In a case in which resin film 30 includes the base sheet and the adhesive layer, after resin film 30 is attached to the first main surface of the substrate, the base sheet is peeled off, and mask 30M may be formed from only the adhesive layer. In the patterning process, in the resin film or adhesive layer 30, a part covering region to be processed R2 is removed, and opening 30W is formed. In the patterning process, for example, a part covering region to be processed R2 of resin film 30 is removed by scribing with laser. If semiconductor substrate 10 is not held by holding sheet 22, after resin film 30 is exposed in a predetermined pattern, a wet etching process in which the film is developed using etching solution may be performed.

Because of the patterning process, first main surface 10S in element region R1 is covered, mask 30M exposing first main surface 10S in region to be processed R2 is formed. A thickness of mask 30M can be, for example, 5 μm to 80 μm. A minimum width (that is, minimum width of opening 30W) of region to be processed R2 may be determined according to a thickness of the mask, the types of the mask, a patterning method, and the like, but for example, may be 20 μm to 40 μm. Next, semiconductor substrate 10 including mask 30M is transported into the processing space of inside vacuum chamber 203 provided in plasma processing apparatus illustrated in FIG. 1, in a state of being held by holding sheet 22 of transportation carrier 20, and mounted on stage 211.

### First Plasma Process

Next, the first gas is introduced from process gas source 212 to the processing space inside vacuum chamber 203 through gas introduction port 203a. A combination of the first gas is not particularly limited, but for example, it is preferable that the first gas may be argon gas.

When power is supplied to ESC electrode 219, holding sheet 22 is adhered to stage 211. Subsequently, when power is supplied from first high-frequency power source 210A to antenna 209 mounted on an upper portion through dielectric member 208, a magnetic field is generated, and the first plasma is generated from the first gas. At this time, pressure inside the processing space may be set to, for example, 0.1 Pa to 100 Pa. When mask 30M is heated by the first plasma in the depressurized atmosphere, as illustrated in FIG. 2D, a void interposed between mask 30M and first main surface 10S of semiconductor substrate 10 is reduced or removed, and adhesion of mask 30M and first main surface 10S is increased.

### Second Plasma Process

Next the first plasma process, the second gas is introduced to the processing space inside vacuum chamber 203 through gas introduction port 203a from process gas source 212. Subsequently, when power is supplied from first high-frequency power source 210A to antenna 209, magnetic field is generated, and the second plasma is generated from the second gas. In the second plasma process, semiconductor substrate 10 is diced by etching region to be processed R2 so as to be divided into individual pieces.

An etching condition of the second plasma process can be appropriately selected according to a material of semiconductor substrate 10.

In a case in which semiconductor substrate 10 is silicon, so-called Bosch process can be used for etching region to be processed R2.

In the Bosch process, a deposition film forming step, a deposition film etching step, and a silicon etching step are sequentially repeated.

Accordingly, region to be processed R2 can be cut in a depth direction.

In the deposition film forming step, for example, C₄F₈ is supplied at 150 sccm to 250 sccm as a material gas, pressure inside the processing space is adjusted to 15 Pa to 25 Pa, supplying power from first high-frequency power source 210A to antenna 209 may set to 1500 W to 2500 W, supplying power from second high-frequency power source 210B to high-frequency electrode 220 may set to 0 W, and a processing time may be set to 5 seconds to 15 seconds. The “sccm” is a unit of an amount of flowing, and 1 sccm is an amount of flowing of air in a normal state (0° C. and 1 atmospheric pressure) to 1 cm³ for one minute.

In the deposition film etching step, for example, while supplying SF₆ at 200 sccm to 400 sccm, pressure inside the processing space is adjusted to 5 Pa to 15 Pa, supplying power from first high-frequency power source 210A to antenna 209 may set to 1500 W to 2500 W, supplying power from second high-frequency power source 210B to high-frequency electrode 220 may set to 100 W to 300 W, and processing time may be set to 2 seconds to 10 seconds.

In the silicon etching step, for example, while supplying SF₆ at 200 sccm to 400 sccm as a material gas, pressure inside the processing space is adjusted to 5 Pa to 15 Pa, supplying power from first high-frequency power source 210A to antenna 209 may set to 1500 W to 2500 W, supplying power from second high-frequency power source 210B to high-frequency electrode 220 may set to 50 W to 200 W, and a processing time may be set to 10 seconds to 20 seconds.

In the condition described above, when the deposition film forming step, the deposition film etching step, and the silicon etching step are repeated, and for example, the silicon substrate can be cut at a velocity of 10 μm/min.

In the second plasma process, it is preferable that holding sheet 22 is electrostatic-sucked to stage 211 by applying voltage to ESC electrode 219. Region to be processed R2 of semiconductor substrate 10 is etched from first main surface 10S to second main surface 10R by the second plasma, and is divided into individual pieces. That is, by the second plasma process, semiconductor substrate 10 is divided into a plurality of element chips 11 including element region R1 (FIG. 2E).

### Ashing Process

Next, an ashing process of removing mask 30M may be performed (FIG. 2F).

The ashing process can be continuously performed inside the processing space where the second plasma process is performed. Process gas for ashing (for example, oxygen gas) is introduced into the processing space from ashing gas source 213 through gas introduction port 203a. When high-frequency power is supplied into the processing space maintained at a predetermined pressure, plasma is generated, and mask 30M is removed from a surface of element chip 11.

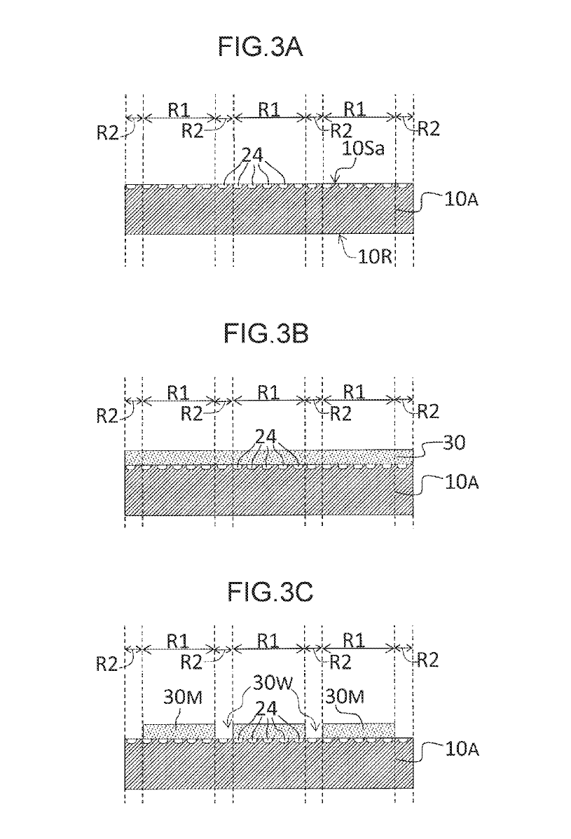

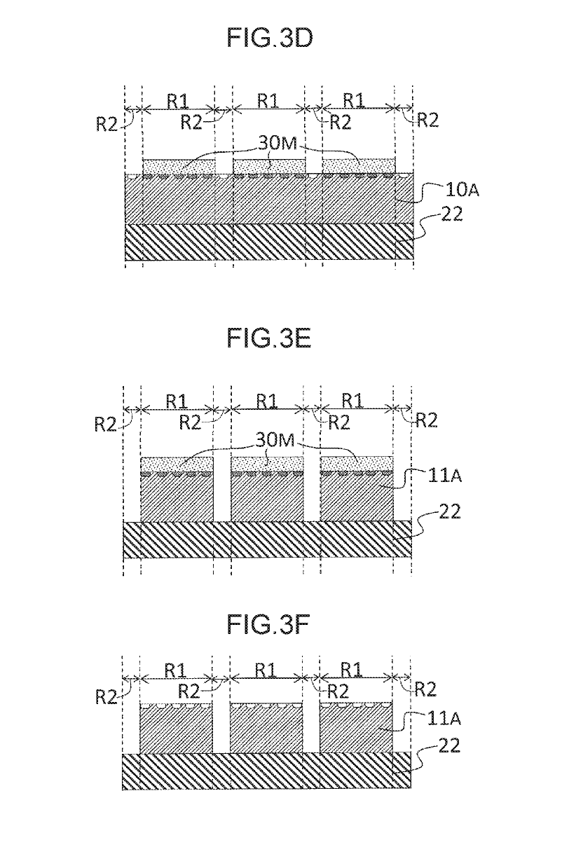

Next, FIG. 3 schematically illustrates a scheme of another plasma processing method according; to the embodiment of the disclosure. The plasma: processing method according to the disclosure is a useful process, as illustrated in FIG. 3A, in a case of etching substrate 10A including a plurality of unevenness on first main surface 10Sa.

In a case in which substrate 10A includes the plurality of unevenness on first main surface 10Sa, when resin film 30 is attached to first main surface 10Sa, between resin film 30 and first main surface 10Sa, a plurality of voids which are caused by a plurality of recesses 24 are formed (FIG. 3B). When resin film 30 is patterned in such a state, a bonding region of formed mask 30M and first main surface 10Sa of substrate 10A is significantly small, a degree of floating of mask 30M is increased (FIG. 3C). At this point, if mask 30M is heated by the first plasma process, as illustrated in FIG. 3D, a phenomenon occurs in which a part of mask 30M (particularly, adhesive layer) becomes soften and charged into recess 24 of first main surface 10Sa. Accordingly, adhesion of mask 30M and first main surface 10Sa is significantly increased. Therefore, the second plasma process which is continuously performed is not affected by the plurality of unevenness, and extra substrate 10A is less likely to be etched FIG. 3E).

Even in this case, when the aching process is performed, since a member which is derived from mask 30M charged into first main surface 10Sa is removed, element chip 11A which maintains unevenness of an initial first main surface 10Sa is obtained (FIG. 3F).

The plasma processing method of the disclosure is useful, for example, in a case in which the mask is formed by pasting the resin film such as a dry film resist and is etched continuously in a precision pattern.

What is claimed is:

1. A plasma processing method comprising:
an attaching process of attaching a resin film to a first main surface of a substrate which is provided with the first main surface and a second main surface on an opposite side of the first main surface;
a patterning process of forming a mask, which includes an opening exposing a region to be processed of the substrate, by patterning the resin film;
a first plasma process of generating first plasma of first gas in a depressurized atmosphere including the first gas, exposing the mask to the first plasma, and reducing a void between the mask and the first main surface; and
a second plasma process of generating second plasma from second gas in atmosphere including the second gas, exposing, to the second plasma, the region to be processed exposed from the opening, and etching the region to be processed.

2. The plasma processing method of claim 1,
wherein, in the first plasma process, the mask is heated with the first plasma, and at least a part of the mask is softened.

3. The plasma processing method of claim 1,
wherein the first gas includes at least one selected from a group of argon, oxygen, nitrogen, and helium.

4. The plasma processing method of claim 1,
wherein pressure of the depressurized atmosphere including the first gas is 0.1 Pa to 100 Pa.

5. The plasma processing method of claim 1,
wherein the first plasma process and the second plasma process are continuously performed in the same space.

6. The plasma processing method of claim 1,
wherein, in the patterning process, a part corresponding to the opening of the resin film is removed by wet-etching.

7. The plasma processing method of claim 1,
wherein, in the patterning process, by scribing using laser, a part, corresponding to the opening, of the resin film is removed.

8. The plasma processing method of claim 1,
wherein, in the second plasma process, the region to be processed is etched from the first main surface to the second main surface, and the substrate is divided into individual pieces.
